(19) United States
(12) Patent Application Publication
(10) Pub. No.: US 2011/0120538 A1
(43) Pub. Date: May 26, 2011

(54) SILICON GERMANIUM SOLAR CELL

(75) Inventors: Anthony Lochtefeld, Ipswich, MA (US); Allen Barnett, Landenberg, PA (US)

(73) Assignee: AMBERWAVE, INC., Salem, NH (US)

(21) Appl. No.: 12/911,678

(22) Filed: Oct. 25, 2010

Related U.S. Application Data
(63) Continuation-in-part of application No. 12/795,207, filed on Jun. 7, 2010.
(60) Provisional application No. 61/254,458, filed on Oct. 23, 2009.
(60) Provisional application No. 61/288,381, filed on Dec. 21, 2009.

(51) Int. Cl. H01L 31/0352; H01L 31/18

(52) U.S. Cl. 136/255; 438/87; 257/E31.032

(57) ABSTRACT

A device, system, and method for a silicon germanium solar cell structure. An exemplary silicon germanium solar cell structure has a substrate with a graded buffer layer grown on the substrate. An absorber layer is grown on the graded buffer layer and an emitter layer is grown on the absorber layer. A first junction is provided between the emitter layer and the absorber layer. A second junction may be provided between the substrate and the graded buffer layer.

### RELATED APPLICATIONS

This application claims the benefit of and priority to U.S. Provisional Application Ser. No. 61/254,458 filed Oct. 23, 2009; U.S. Provisional Application Ser. No. 61/288,381 filed Dec. 21, 2009; a continuation of U.S. Utility application Ser. No. 12/795,207 filed Jun. 7, 2010, the disclosures of which are hereby incorporated by reference in their entirety.

### TECHNICAL FIELD

The present invention relates to solar cells and more particularly, relates to a silicon germanium solar cell.

### BACKGROUND

There is considerable interest in the design and fabrication of tandem multi-junction solar cells for high efficiency photovoltaics for space-based and terrestrial applications. Multi-junction solar cells consist of two or more p-n junction subcells with band gaps engineered to enable efficient collection of the broad solar spectrum. The subcell band gaps are controlled such that as the incident solar spectrum passes down through the multi-junction solar cell it passes through subcells of sequentially decreasing band gap energy. Thus, the efficiency losses associated with single-junction cells—inefficient collection of high-energy photons and failure to collect low-energy photons—are minimized.

### SUMMARY

The present invention is a novel device, system, and method for silicon germanium solar cell structure. An exemplary structure may have a substrate with a silicon germanium graded buffer layer grown on the substrate. An absorber layer may be provided in the graded buffer layer or on top of the graded buffer layer. An emitter layer may be provided on the absorber layer. A first junction may be provided between the emitter layer and the absorber layer. According to another aspect, a second junction may be provided between the bottom of the substrate and the graded buffer layer. According to yet another aspect, the first junction may have a reduced junction area utilizing epitaxial lateral overgrowth.

Among the many different possibilities contemplated, in one aspect the substrate is silicon, the graded buffer layer composition is graded silicon germanium, and the absorber layer composition is Si₍₁₋ₓ₎Geₓ with x equal from about 0.2 to about 1. In another aspect, the graded buffer layer has a grade rate of about 10-50 percent germanium per micron of graded buffer layer thickness.

The present invention is not intended to be limited to a system or method that must satisfy one or more of any stated objects or features of the invention. It is also important to note that the present invention is not limited to the exemplary or primary embodiments described herein. Modifications and substitutions by one of ordinary skill in the art are considered to be within the scope of the present invention, which is not to be limited except by the following claims.

### BRIEF DESCRIPTION OF THE DRAWINGS

These and other features and advantages of the present invention will be better understood by reading the following detailed description, taken together with the drawings wherein:

FIG. 1 is a profile diagram of a silicon germanium solar cell structure constructed in accordance with an exemplary single junction embodiment of the invention.

FIG. 2 is a profile diagram of a more detailed silicon germanium cell structure constructed in accordance with the exemplary single junction cell embodiment of the invention.

FIG. 3 is a flow chart of exemplary actions used to construct a device in accordance with the exemplary single junction cell embodiment of the invention.

FIG. 4 is a profile diagram of a silicon germanium solar cell structure constructed in accordance with an exemplary dual junction embodiment of the invention.

FIG. 5 is a profile diagram of a more detailed silicon germanium solar cell structure constructed in accordance with the exemplary dual junction cell embodiment of the invention.

FIG. 6 is a flow chart of an exemplary action used to construct a device in accordance with the exemplary dual junction cell embodiment of the invention.

FIGS. 7a and 7b are profile diagrams of a solar cell structure constructed in accordance with an exemplary dual junction cell with contacts embodiment of the invention.

FIG. 8 is a flow chart of exemplary actions used to construct a device in accordance with the exemplary dual junction cell with contacts embodiment of the invention.

FIG. 9 is a profile diagram of a concentrated solar cell structure constructed in accordance with the exemplary concentrated dual junction cell embodiment of the invention.

FIG. 10 is a profile diagram of a silicon germanium solar cell structure constructed in accordance with an exemplary dual junction cell with reduced junction area embodiment of the invention.

FIG. 11 is a flow chart of more detailed exemplary actions used to construct a device in accordance with the exemplary silicon germanium dual junction cell with reduced junction area embodiment of the invention.

FIG. 12 is a profile diagram of a reduced junction area structure constructed in accordance with the exemplary dual junction cell with reduced junction area embodiment of the invention.

### DETAILED DESCRIPTION OF THE PREFERRED EMBODIMENTS

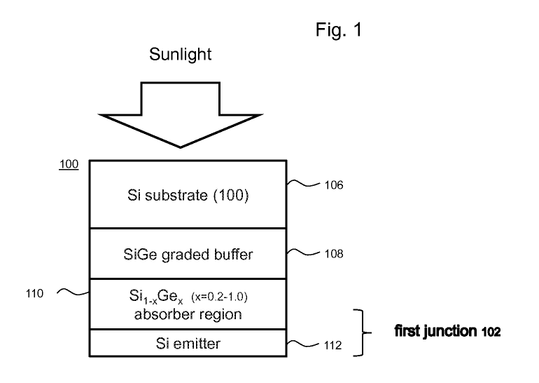

Referring to FIG. 1, a silicon germanium junction solar cell structure 100 has a first junction 102 according to an exemplary silicon germanium junction embodiment of the invention. A silicon (100) wafer, for example, may be used as a substrate 106 for fabrication of the solar cell. A graded buffer layer 108 may be used to grow the first junction 102. The first junction 102 may be a P doped silicon germanium absorber layer 110 and N doped silicon emitter layer 112 to provide a p-n type junction. The absorber layer 110 may be provided throughout the graded buffer layer 108 or may be a separate layer grown on top of the graded buffer layer 108.

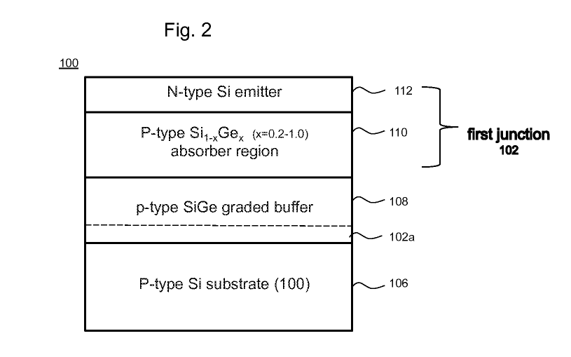

Referring to FIG. 2, it is important to note that the structure has been flipped upside-down from the structure of FIG. 1 to better illustrate the construction of solar cell 100. The graded buffer 108 is hetero-epitaxially grown on the substrate 106. An exemplary process is described in greater detail in U.S. Pat. No. 7,041,170 of May 9, 2006 entitled: “Method of Producing High Quality Relaxed Silicon Germanium Layers”. The first junction 102 may be produced using the graded buffer 108 of silicon germanium. The initial growth may include a low composition of germanium with successive growth having a gradually increasing germanium composition. An N doped silicon layer may be grown to produce the emitter 112 on an absorber region 110 of the graded buffer 108. The N doped silicon emitter 112 and P doped absorber region 110 produce the first junction 102.

A first contact (not shown) may be made to the exposed surface of the emitter layer 112. A second contact (not shown) may be made to the exposed surface of the substrate 106.

According to the single junction embodiment, either surface can be exposed to the light. Light below the silicon bandgap energy may freely pass through the whole substrate. Regardless of which surface is exposed to the sun, both the surface of the emitter and the bottom surface of the substrate may be passivated, e.g. by thermal oxidation or by PECVD SiNx.

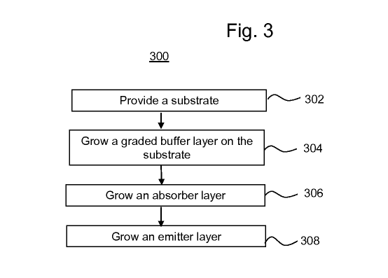

Referring to FIG. 3, an exemplary method of constructing a silicon germanium solar cell 300 is shown according to an exemplary embodiment of the invention. The substrate 106 is provided for fabrication of the silicon germanium solar cell 100 (block 302). The wafer may be a monocrystalline silicon wafer with a (1,0,0) crystal face orientation. Wafers are commercially available in a range of sizes from 25.4 mm (1 inch) to 300 mm (11.8 inches). For the case of P-absorber and N-emitter, for a single junction cell, the substrate doping may be P-type, e.g. 0.1-100 ohm-cm. The graded buffer is doped p-type, typically to the same resistivity as the substrate. The first junction 102 may be P doped silicon germanium absorber 110 and N doped silicon emitter 112 to provide a p-n type junction. A graded buffer layer 108 may be used to grow the first junction 102 (block 304). The graded buffer layer may have a grade rate of about 10-50 percent germanium per micron of graded buffer layer thickness. The absorber layer 110 may be incorporated into the graded buffer layer 108 or may be a separate layer grown on the top of the graded buffer layer 108 (block 306). For example, the absorber layer 110 composition may be Si₍₁₋ₓ)Geₓ with x equal from about 0.2 to about 1. In another example, the absorber layer 110 may be a separate germanium or SiGe layer grown on the graded buffer layer 108. An emitter layer 112 may be grown on the absorber layer 110 (block 308). The emitter layer 112 may be, for example, an N doped silicon layer. Embodiments of the method may include incorporation of contacts and removal of the substrate or additional layers.

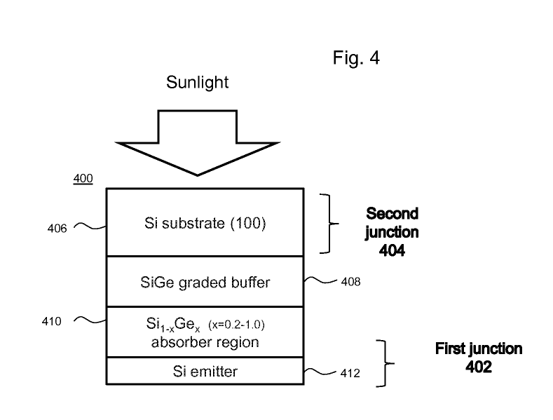

Referring to FIG. 4, a silicon germanium dual junction solar cell structure 400 has a first junction 402 and a second junction 404 according to an exemplary dual junction cell embodiment of the invention. A substrate 406 for the first junction 402 may be produced with, for example, a silicon (100) substrate. One side of the substrate 406 may be doped to provide the second p-n type junction 404. The first junction 402 may be P doped silicon germanium absorber 408 and N doped silicon emitter 410 to provide the first p-n type junction 402. A graded buffer layer 408 may be used to grow the first junction 402 as previously described in prior embodiments. The band gaps of each junction may be engineered to enable efficient collection of the broad solar spectrum as light passes through the first junction 402 and to the second junction 404.

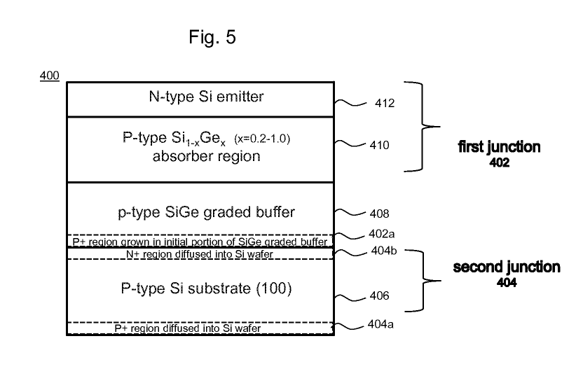

Referring to FIG. 5, a dual junction solar cell structure 400 is provided according to an exemplary dual junction cell embodiment of the invention. It is important to note that again the structure has been flipped upside-down from the structure of FIG. 4 to better illustrate the construction of solar cell. The second junction 404, located on the bottom of the diagram may again be a substrate 406 made of silicon (100). The second junction 404 may include a P doped surface 404a to allow good electrical contacts to be subsequently formed to the substrate, and an N doped surface 404b to produce a P-N junction. The doping may be produced by, for example, diffusion, ion implant, or other methods of doping. The first junction 402 is then hetero-epitaxially grown on the substrate 406. The first junction 402 may be produced using a graded buffer 408 of silicon germanium. The initial growth may include a low composition of germanium with successive growth having a gradually increasing germanium to silicon composition. The initial growth may also include a highly P+ typed doped initial region 402a to allow tunnel junction to form between the N doped surface 404b of the first junction 402. An N doped silicon layer may be grown to produce an emitter 412 on an absorber region 410 of the graded buffer 408. The N doped silicon emitter 412 and P doped absorber region 410 produce the first junction 402.

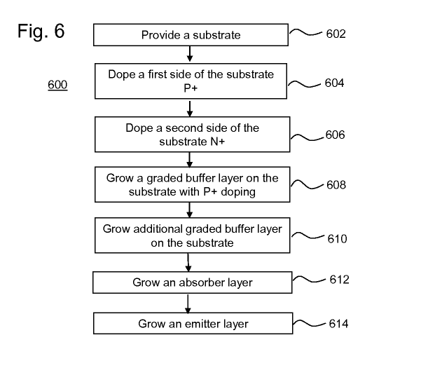

Referring to FIG. 6, an exemplary method of constructing a silicon germanium dual junction solar cell 600 is shown according to an exemplary embodiment of the invention. The substrate 406 is provided for fabrication of the silicon germanium solar cell 400 (block 602). The wafer may be a monocrystalline silicon wafer with a (1,0,0) crystal face orientation. Wafers are commercially available in a range of sizes from 25.4 mm (1 inch) to 300 mm (11.8 inches). The substrate may be P-type doped. A first surface of the substrate 406 may be P doped (block 604) and the second surface, opposite the first surface, may be N doped (block 606). The resulting substrate 406 provides a P-N junction for the second solar cell junction 404. The substrate 406 may be used to grow a structure for the first junction 402. The initial growth may also include a highly P+ typed doped initial region 402a to allow tunnel junction to form between the N doped surface 404b of the first junction 402 (block 608). The graded buffer layer 408 may be used to grow the first junction 402 (block 610). The graded buffer layer may have a grade rate of about 10-50 percent germanium per micron of graded buffer layer thickness. The absorber layer 410 may be incorporated into the graded buffer layer 408 or may be a separate layer grown on the top of the graded buffer layer 408 (block 612). For example, the absorber layer 410 composition may be Si₍₁₋ₓ₎Geₓ with x equal from about 0.2 to about 1. In another example the absorber layer 410 may be a separate germanium or SiGe layer grown on the graded buffer layer 408. An emitter layer 412 may be grown on the absorber layer 410 (block 614). The emitter layer 112 may be, for example, an N doped silicon layer. Embodiments of the method may include incorporation of contacts and additional layers or removal of the substrate or other portions.

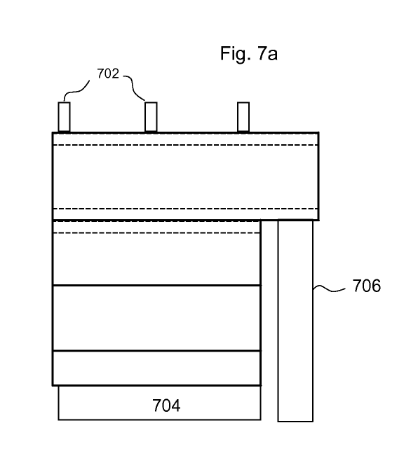

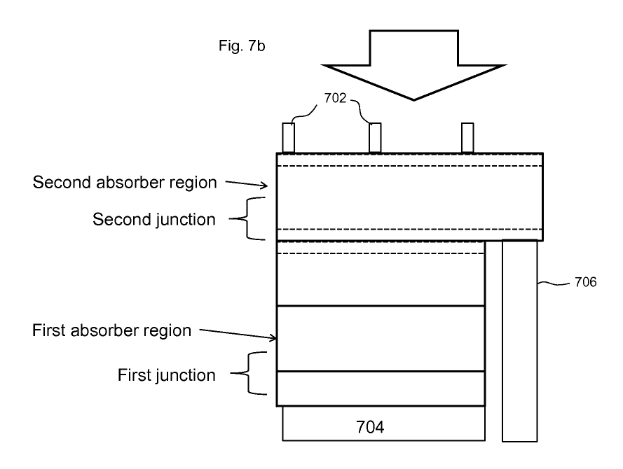

Referring to FIGS. 7a and 7b, a solar cell structure 700 with contacts is constructed in accordance with an exemplary dual junction cell embodiment of the invention. A second contact 702 for the second junction 404 may be provided on the exposed surface of the substrate 406. A first contact 704 for the first junction 402 may be provided on the exposed surface of the emitter 412. A middle contact 706 between the first junction 402 and second junction 404 may be provided. The middle contact 706 may be provided by producing vias through the substrate 406, graded buffer 408 and absorber layer 410. The middle contact may allow operation of the solar cell without the requirement of current matching. It is important to note that the electrical connection is not limited to the above described contacts. Various electrical connections and configurations may be provided and are within the scope of the invention.

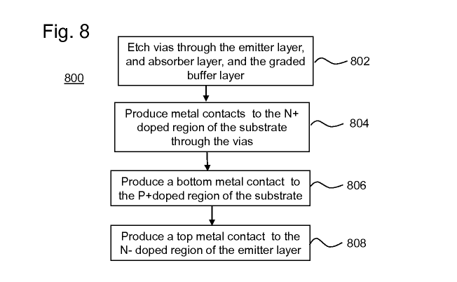

Referring to FIG. 8, an exemplary method of constructing a silicon germanium dual junction solar cell 800 with contacts 600 is shown according to an exemplary embodiment of the invention. The emitter layer 406, and absorber layer 410, and the graded buffer layer 408 are etched through (block 802). Middle contacts 706 are produced to electrically couple to the N+ doped region 404b of the substrate 406 through the vias (block 804). The second contact 702 is produced to electrically couple to the P doped region 404A of the substrate 406 (block 806). The first contact 704 is produced to electrically couple to the emitter 412 (block 808).

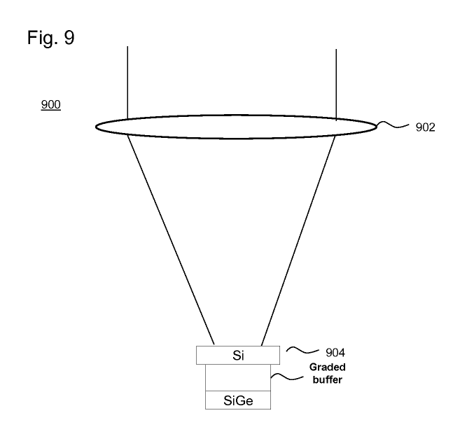

Referring to FIG. 9, a concentrated solar cell structure 900 is constructed in accordance with the exemplary concentrated dual junction cell embodiment of the invention. The concentrator 902 is used to focus light onto a solar cell 904 to optimize the efficiency of solar power. The concentrator 902 allows for the greater collection of light and/or the focusing of light directly onto the solar cell 904. The concentrator 902 or solar cell 904 may be coupled to an actuator to move or rotate to allow for better direct collection of sunlight as the sun rotates through the horizon.

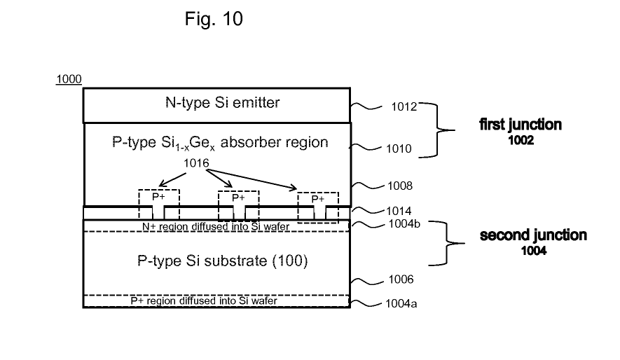

Referring to FIG. 10, a silicon germanium dual junction with reduced junction area solar cell structure 1000 has a first junction 1002 and a second junction 1004 according to an exemplary dual junction cell embodiment of the invention. A substrate 1006 for the first junction 1002 may be produced with, for example, a silicon (100) substrate. The opposing sides of the substrate 1006 may be doped to provide the second p-n type junction 1004. The first junction 1002 may be P doped silicon germanium reduced junction absorber 1008 and N doped silicon emitter 1010 to provide the first p-n type junction 1002. A silicon oxide layer 1014 may be thermally grown on the substrate 1006. Utilizing photolithography, patterns may be defined within the silicon oxide layer 1014. The patterns may have different geometries and configurations. Epitaxial lateral overgrowth may be used to grow reduced junction areas 1016 of silicon or silicon germanium. A graded buffer layer 1008 may be used to grow the rest of first junction 1002 as previously described in prior embodiments. An N doped silicon layer may be grown to produce an emitter 1012 on an absorber region 1010. The N doped silicon emitter 1012 and P doped absorber region 1010 with reduced junction area 1014 produce the first junction 1002.

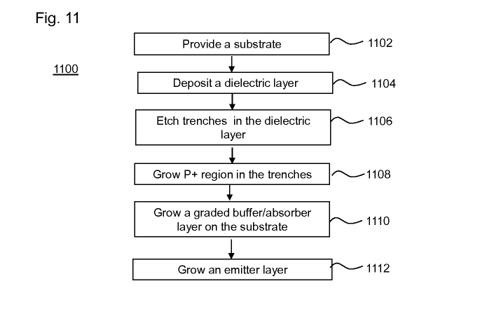

Referring to FIG. 11, an exemplary method of constructing a silicon germanium dual junction solar cell with reduced junction area 1100 is shown according to an exemplary embodiment of the invention. The substrate 1006 is provided for fabrication of the silicon germanium solar cell 400 (block 1102). The wafer may be a monocrystalline silicon wafer with a (1,0,0) crystal face orientation. Wafers are commercially available in a range of sizes from 25.4 mm (1 inch) to 300 mm (11.8 inches). A first surface of the substrate 1006 may be P doped and the second surface, opposite the first surface, may be N doped. The resulting substrate 1006 provides a P-N junction for the second solar cell junction 1004. The substrate 1006 may be used to grow a structure for the first junction 1002. A dielectric layer 1014 of silicon dioxide may be thermally grown on the substrate 1006 (block 1104). Utilizing photolithography or other removal process, different patterns and geometries may be used to etch through the dielectric layer 1014 (block 1106). After the cleaning of the patterned surface, P type silicon or silicon germanium may be grown by chemical vapor deposition using the method of epitaxial lateral overgrowth (block 1108). The graded buffer layer 1108 may be used to grow the absorber region 1110 (block 1110). An emitter layer 1012 may be grown on the absorber layer 1010 (block 1112). The emitter layer 112 may be, for example, an N doped silicon layer. Embodiments of the method may include incorporation of contacts and removal of the substrate or other portions as previously discussed. The structure and method of the reduced junction area embodiment is not limited to a dual junction solar cell. The structure and method may be combined with the single cell structure embodiment to provide a single cell with reduced junction area.

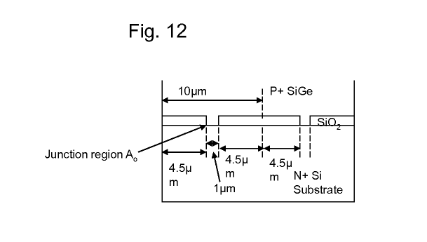

Referring to FIG. 12, the cross section view with exemplary dimensions is shown for the pattern/trench in block 1108. The line width is 1 μm and the line spacing is 10 μm. The ratio of light generation area to junction area is 10. According to the equations (1), the theoretical increase of open circuit voltage is around 59.4 mV compared with the usual structure for which the light generation region area is the same as the junction region area.

$$Voc = \frac{kT}{q} ln ( \frac{{A}_{L} {J}_{L}}{{A}_{0} {J}_{0}} + 1 )$$

Therefore, by using the exemplary structure, an improvement in open circuit voltage may be achieved. The ratio of light generation region area to junction area can be designed larger to have greater improvement in V_{oc}. To realize this structure, the processing may utilize photolithography, epitaxial lateral overgrowth and basic silicon solar cell processing technique. A preferred ratio of the trench may have a height to width ratio of greater than one.

Other modifications and substitutions by one of ordinary skill in the art are considered to be within the scope of the present invention, which is not to be limited except by the following claims.

The invention claimed is:

1. A silicon germanium solar cell structure comprising:
a substrate;
a silicon germanium graded buffer layer grown on the substrate;
an absorber layer; and
an emitter layer on the absorber layer wherein a first junction is provided between the emitter layer and the absorber layer.

2. The silicon germanium cell structure of claim 1, wherein substrate is silicon, the graded buffer layer composition is graded silicon germanium, and the absorber layer composition is Si₍₁₋ₓ₎Geₓ with x equal from about 0.2 to 1.

3. The silicon germanium cell structure of claim 2, wherein the emitter is silicon.

4. The silicon germanium cell structure of claim 1, wherein the graded buffer layer has a grade rate of about 10-50 percent germanium per micron of graded buffer layer thickness.

5. The silicon germanium cell structure of claim 1, further comprises:
a first contact on a top surface of the emitter layer; and
a second contact on a bottom surface of the substrate.

6. The silicon germanium cell structure of claim 1, wherein substrate is silicon, the graded buffer layer composition is graded silicon germanium, and the absorber layer composition is Si₍₁₋ₓ₎Geₓ with x equal from about 0.2 to 1, and the emitter is silicon.

7. A silicon germanium solar cell structure comprising:
a substrate;
a silicon germanium graded buffer layer grown on the substrate wherein;
an absorber layer; and
an emitter layer on the absorber layer wherein a first junction is provided between the emitter layer and the absorber layer and a second junction is provided between a bottom of the substrate and the graded buffer layer.

8. The silicon germanium cell structure of claim 7, wherein substrate is silicon, the graded buffer layer composition is graded silicon germanium, and the absorber layer composition is Si₍₁₋ₓ₎Geₓ with x equal from about 0.2 to 1.

9. The silicon germanium cell structure of claim 7, wherein the graded buffer layer has a grade rate of about 10-50 percent germanium per micron of graded buffer layer thickness.

10. The silicon germanium cell structure of claim 7, wherein the substrate is silicon and has a first P+ doped surface and a second N+ doped surface.

11. The silicon germanium cell structure of claim 10, wherein the first P+ doped surface and the second N+ doped surface provide a top solar cell.

12. The silicon germanium cell structure of claim 7, wherein the graded buffer layer has an initial P+ doped region.

13. The silicon germanium cell structure of claim 12, wherein the initial P+ doped region and the emitter layer provide a bottom solar cell.

14. The silicon germanium cell structure of claim 7, further comprises:
a first contact on a top surface of the emitter layer;
a second contact on a bottom surface of the substrate; and
a middle contact on a top surface of the substrate.

15. The silicon germanium cell structure of claim 14, wherein the second contact and the middle contact provide a top solar cell and the first contact and the middle contact provide a bottom solar cell.

16. A method of making a silicon germanium solar comprising the actions:
providing a substrate;
growing a silicon germanium graded buffer layer on the substrate;
growing an absorber layer; and
growing an emitter layer on the absorber layer wherein a first junction is provided between the emitter layer and the absorber layer and a second junction is provided between a first surface of the substrate and the graded buffer layer.

17. The method of making a silicon germanium cell of claim 16, wherein substrate is silicon, the graded buffer layer composition is graded silicon germanium, and the absorber layer composition is Si₍₁₋ₓ₎Geₓ with x equal from about 0.2 to about 1.

18. The method of making a silicon germanium cell of claim 16, wherein the graded buffer layer has grade rate of about 10-50 percent germanium per micron of growth.

19. The method of making a silicon germanium cell of claim 16, further comprises the action of:
doping a first surface of the substrate P+, doping a second surface opposite the first surface of the substrate N+,
doping an initial region of the graded buffer layer P+, and
doping the emitter layer N+.

20. The method of making a silicon germanium cell of claim 21, further comprises the action of:
producing a second contact on a first surface of the substrate opposite the graded buffer layer;
producing a first contact on a surface of the emitter layer opposite the graded buffer layer; and
producing a middle contact on a second surface opposite the first surface of the substrate.
